(19) United States
(12) Patent Application Publication
(10) Pub. No.: US 2026/0190945 A1
(43) Pub. Date: Jul. 2, 2026

(54) DICING/DIE-BONDING INTEGRATED FILM AND METHOD FOR MANUFACTURING THE SAME

(71) Applicant: Resonac Corporation, Minato-ku, Tokyo (JP)

(72) Inventors: Keisuke OHKUBO, Minato-ku, Tokyo (JP); Satoshi YABUSHITA, Minato-ku, Tokyo (JP); Naohiro KIMURA, Minato-ku, Tokyo (JP); Tetsuya TANIGUCHI, Minato-ku, Tokyo (JP); Yukihiro IWANAGA, Minato-ku, Tokyo (JP); Miharu KOSHINO, Minato-ku, Tokyo (JP)

(21) Appl. No.: 18/860,699

(22) PCT Filed: Apr. 17, 2024
(86) PCT No.: PCT/JP2024/015326

§ 371 Date: Oct. 28, 2024

(30) Foreign Application Priority Data
Sep. 25, 2023 (JP) 2023-160097

(51) Int. Cl. H10P 72/70; H10P 54/92; H10P 58/00

(52) U.S. Cl. CPC H10P 72/742; H10P 54/924; H10P 58/20; H10P 72/7402

(57) ABSTRACT

A dicing/die-bonding integrated film 10 including a dicing film 5 including a substrate film 3 and a pressure-sensitive adhesive layer 2 provided on the substrate film 3, and a bonding adhesive layer composed of a die-bonding film 1 disposed on the pressure-sensitive adhesive layer 2 of the dicing film 5. The loss tangent of the dicing film 5 at 0° C. is 0.15 or less.

### TECHNICAL FIELD

The present disclosure relates to a dicing/die-bonding integrated film and a method for manufacturing the same.

### BACKGROUND ART

The semiconductor device is manufactured through the following steps. First, a dicing step is performed with a pressure-sensitive adhesive film for dicing attached to a wafer. Thereafter, an expanding step, a pickup step, a die bonding step, and the like are performed.

In a manufacturing process of a semiconductor device, a dicing/die-bonding integrated film in which a dicing film having a substrate film and a pressure-sensitive adhesive layer and a die-bonding film for bonding a substrate or another semiconductor chip to each other are integrated may be used. The dicing/die-bonding integrated film is used, for example, as follows. First, a surface on a die-bonding film (bonding adhesive layer) side is attached to a wafer, and the wafer is diced in a state where the wafer is fixed with a dicing ring. As a result, the wafer is individualized into a large number of chips. Subsequently, the pressure-sensitive adhesive layer is irradiated with an ultraviolet ray to reduce the pressure-sensitive adhesive force of the pressure-sensitive adhesive layer to the die-bonding film, and then a chip is picked up from the pressure-sensitive adhesive layer together with a die-bonding film piece obtained by individuating the die-bonding film. Thereafter, the semiconductor device is manufactured through a step of mounting the chip on the substrate or the like via the die-bonding film piece. Note that a layered body composed of a chip obtained through the dicing step and a die-bonding film piece attached to the chip is referred to as a chip with a die-bonding film piece.

Conventionally, blade dicing, which is cutting with a blade or the like, is widely known as a dicing method of a wafer and a bonding adhesive layer. In recent years, stealth dicing has become widespread with high integration of a semiconductor package and thinning of a wafer (See Patent Literatures 1 and 2). Stealth dicing is a method in which a line to cut is formed inside an object to be processed by a laser, and then a wafer and a die-bonding film are cut along the line to cut to obtain a chip with a die-bonding film piece.

### CITATION LIST

### Patent Literature

Patent Literature 1: Japanese Unexamined Patent Publication No. 2002-192370
Patent Literature 2: Japanese Unexamined Patent Publication No. 2003-338467

### SUMMARY OF INVENTION

### Technical Problem

In a manufacturing process of a semiconductor device, when a reformation region is formed and split by stealth dicing, expansion under cooling conditions (for example, 0° C. or lower) (Hereinafter, “cooling expansion” may be referred to.) may be performed. However, when a conventional dicing/die-bonding integrated film is applied to cooling expansion, the die-bonding film may be difficult to be split in the cooling expansion. If the die-bonding film is not easily split, it is difficult to pick up the semiconductor chip with the die-bonding film piece, and the yield may be reduced in the manufacture of the semiconductor device.

A main object of the present disclosure is to improve cooling splitting properties of a die-bonding film in a method for manufacturing a predetermined semiconductor device.

### Solution to Problem

The present disclosure includes [1] to [6].

[1]

A dicing/die-bonding integrated film comprising: a dicing film including a substrate film and a pressure-sensitive adhesive layer provided on the substrate film; and a bonding adhesive layer composed of a die-bonding film and disposed on the adhesive layer of the dicing film, wherein a loss tangent at 0° C. of the dicing film is 0.15 or less, wherein the loss tangent is a value determined by a method including: preparing a measurement sample of the dicing film having a rectangular principal surface with a short side of 5 mm and a long side of 8 mm; fixing, in a viscoelasticity measuring device (Rheogel-E4000, manufactured by UBM Co., Ltd.) including a solid shearing jig having a first plate-shaped member and a pair of second plate-shaped members, the measurement sample to the solid shearing jig by disposing two of the measurement samples in a direction in which the principal surface of the pressure-sensitive adhesive layer is in contact with the first plate-shaped member and the first plate-shaped member is sandwiched between the two measurement samples to clamp the measurement sample in a thickness direction under a condition that the clamping pressure applied by each of the pair of second plate-shaped members is a torque wrench 9 cN·m, and determining the loss tangent by dynamic viscoelasticity measurement in a shear mode using the solid shearing jig to which the measurement sample is fixed under the conditions that a measurement frequency is 10 Hz, a strain amount is 1% in terms of a total thickness ratio of the dicing film, and a temperature raising rate is 2° C./min.

[2]

The dicing/die-bonding integrated film according to [1], wherein a loss tangent of the dicing film at 0° C. is 0.07 or less.

[3]

The dicing/die-bonding integrated film according to [1] or [2], wherein the pressure-sensitive adhesive layer has a thickness of 10 μm or less.

[4]

A method for manufacturing a dicing/die-bonding integrated film, the method including: a step of selecting a dicing film including a substrate film and a pressure-sensitive adhesive layer provided on the substrate film, the dicing film having a loss tangent at 0° C. of 0.15 or less; and a step of bonding a die-bonding film and the pressure-sensitive adhesive layer of the dicing film, wherein the loss tangent is a value determined by a method including: preparing a measurement sample of the dicing film having a rectangular principal surface with a short side of 5 mm and a long side of 8 mm; fixing, in a viscoelasticity measuring device (Rheogel-E4000, manufactured by UBM Co., Ltd.) including a solid shearing jig having a first plate-shaped member and a pair of second plate-shaped members, the measurement sample to the solid shearing jig by disposing two of the measurement samples in a direction in which the principal surface of the pressure-sensitive adhesive layer is in contact with the first plate-shaped member and the first plate-shaped member is sandwiched between the two measurement samples to clamp the measurement sample in a thickness direction under a condition that the clamping pressure applied by each of the pair of second plate-shaped members is a torque wrench 9 cN·m, and determining the loss tangent by dynamic viscoelasticity measurement in a shear mode using the solid shearing jig to which the measurement sample is fixed under the conditions that a measurement frequency is 10 Hz, a strain amount is 1% in terms of a total thickness ratio of the dicing film, and a temperature raising rate is 2° C./min.

### Advantageous Effects of Invention

According to the present disclosure, it is possible to improve cooling splitting properties of a die-bonding film in a method for manufacturing a predetermined semiconductor device.

### BRIEF DESCRIPTION OF DRAWINGS

FIG. 1 is a schematic cross-sectional view showing one embodiment of a dicing film.

FIG. 2 is a schematic diagram for explaining a method for measuring a loss tangent of a dicing film at 0° C.

FIG. 3 is a schematic cross-sectional view showing one embodiment of a dicing/die-bonding integrated film.

FIG. 4 is a cross-sectional view schematically illustrating a method of manufacturing a semiconductor device, and FIGS. 4(a), 4(b), and 4(c) are cross-sectional views schematically illustrating each step.

FIG. 5 is a cross-sectional view schematically illustrating a method of manufacturing a semiconductor device, and FIGS. 5(a) and 5(b) are cross-sectional views schematically illustrating each step.

### DESCRIPTION OF EMBODIMENTS

Hereinafter, embodiments of the present disclosure are described with appropriate reference to the drawings. However, the present disclosure is not limited to the following embodiments. In the following embodiments, the components (including steps and the like) are not essential unless otherwise specified. The sizes of the components in the drawings are conceptual, and the relative relationship between the sizes of the components is not limited to that illustrated in the drawings.

The same applies to numerical values and ranges thereof in the present specification, and the present disclosure is not limited thereto. In the present specification, a numerical range indicated using “to” indicates a range including numerical values described before and after “to” as a minimum value and a maximum value, respectively. In the numerical ranges described in stages in the present specification, the upper limit value or the lower limit value described in one numerical range may be replaced with the upper limit value or the lower limit value of the numerical range described in another stage. In addition, in the numerical range described in the present specification, the upper limit value or the lower limit value of the numerical range may be replaced with a value shown in Examples.

In the present specification, the “(meth)acrylate” means at least one of an acrylate and a methacrylate corresponding thereto. The same applies to other similar expressions such as “(meth)acryloyl”. “A or B” may include either A or B, or may include both A and B. The materials exemplified below may be used alone or in combination of two or more unless otherwise specified. The content of each component in the composition means, when a plurality of substances corresponding to each component are present in the composition, the total amount of the plurality of substances present in the composition unless otherwise specified.

### [Dicing Film]

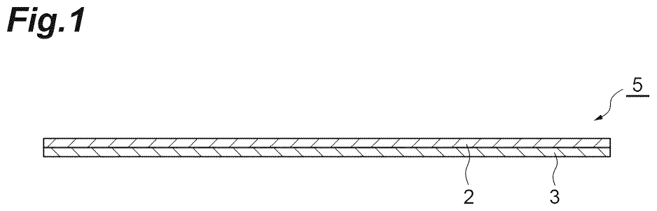

FIG. 1 is a schematic cross-sectional view showing an embodiment of a dicing film (dicing tape). A dicing film 5 shown in FIG. 1 includes a substrate film 3 and a pressure-sensitive adhesive layer 2 provided on the substrate film 3. The substrate film 3 has, for example, a rectangular principal surface. The principal surface of the pressure-sensitive adhesive layer 2 may be the same size as the principal surface of the die-bonding film.

### <Loss Tangent (tan δ)>

The loss tangent of the dicing film 5 at 0° C. is 0.15 or less. The loss tangent is the ratio of the loss modulus to the storage modulus. In the measurement of the loss tangent, a dynamic viscoelasticity measuring device (Rheogel-E4000, manufactured by UBM Co., Ltd.) including a solid shearing jig is used.

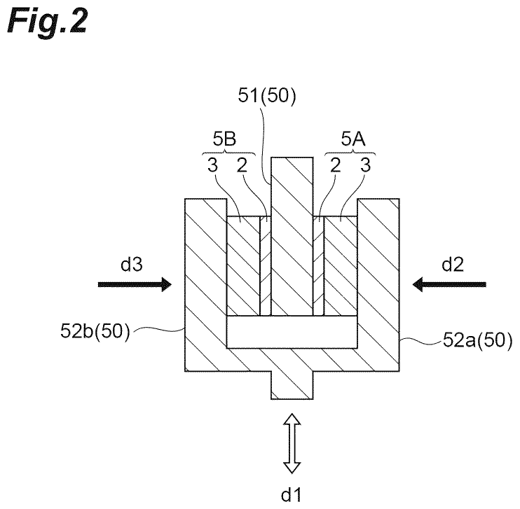

FIG. 2 is a schematic diagram for explaining a method of measuring a loss tangent. Two measurement samples 5A and 5B including the pressure-sensitive adhesive layer 2 and the substrate film 3 are fixed to a solid shearing jig 50. The solid shearing jig 50 includes a first plate-shaped member 51 and a pair of second plate-shaped members 52a and 52b that can fix the measurement samples 5A and 5B by clamping the measurement samples 5A and 5B in the directions indicated by the directions d2 and d3, which are the thickness directions of the measurement samples 5A and 5B, and can vibrate in the directions indicated by the direction d1. Each of the first plate-shaped member 51 and the second plate-shaped members 52a and 52b may be a plate-shaped member made of stainless steel (SUS). The stress is applied to the measurement samples 5A and 5B in the shearing direction (direction d1) by vibrating the measurement samples 5A and 5B in the direction indicated by d1 while the first plate-shaped member is fixed to the dynamic viscoelasticity measuring device, and the measurement samples 5A and 5B are fixed to the solid shearing jig 50 by the second plate-shaped members 52a and 52b.

The measurement samples 5A and 5B are disposed so as to sandwich the first plate-shaped member 51 in a direction in which the principal surface of the pressure-sensitive adhesive layer 2 is in contact with the first plate-shaped member 51. The measurement samples 5A and 5B are disposed such that the principal surface on the substrate film 3 side is in contact with the second plate-shaped members 52a and 52b, respectively. The measurement samples 5A and 5B are fixed to the solid shearing jig 50 by being clamped from the directions d2 and d3 by the pair of second plate-shaped members 52a and 52b. The principal surface of the first plate-shaped member 51 in contact with the pressure-sensitive adhesive layer 2 may have the same or substantially the same size as the principal surface of the pressure-sensitive adhesive layer 2 of the measurement samples 5A and 5B. The principal surfaces of the second plate-shaped members 52a and 52b in contact with the substrate film 3 may have the same or substantially the same size as the principal surfaces of the substrate films 3 of the measurement samples 5A and 5B.

As the measurement samples 5A and 5B, a dicing film 5 to be measured having a rectangular principal surface with a short side of 5 mm and a long side of 8 mm is used. The measurement samples 5A and 5B are samples produced from the same dicing film to be measured, and are produced by cutting the dicing film 5 to be measured as necessary.

The measurement samples 5A and 5B are fixed to the solid shearing jig 50 so as to be in the same direction as the direction d1 in which the solid shearing jig 50 vibrates, with the MD direction of the substrate film 3 as a short side. The measurement samples 5A and 5B are fixed to the solid shearing jig 50 in a direction orthogonal to the direction d1 in which the solid shearing jig 50 vibrates with the TD direction of the substrate film 3 as a long side. The MD direction (machine direction) is a direction (flow direction) parallel to the longitudinal direction in the original fabric for providing the substrate film 3. The TD direction (Transverse Direction) is a direction (vertical direction) orthogonal to the MD direction.

The measurement samples 5A and 5B are fixed to the solid shearing jig by being clamped from the thickness directions d2 and d3 by the pair of second plate-shaped members 52a and 52b under the condition that the clamping pressure is the torque wrench 9 cN·m.

The measurement by the dynamic viscoelasticity measuring device is performed under the conditions that the measurement frequency is 10 Hz, the strain amount is 1% in terms of the total thickness ratio of the dicing film, and the temperature raising rate is 2° C./min. The measurement temperature range may be −20° C. to 60° C. The loss tangent is determined by dynamic viscoelasticity measurement in a shear mode using the solid shearing jig 50 to which the measurement samples 5A and 5B are fixed. The strain amount is a set value for dynamic viscoelasticity measurement.

The loss tangent at 0° C. is 0.15 or less. When the loss tangent at 0° C. is 0.15 or less, splitting properties by cooling expansion is improved. The present inventors infer that when the loss tangent is 0.15 or less, the loss of the breaking stress caused by the dicing film in the cooling expansion becomes sufficiently small, and as a result, the stress transmitted to the die-bonding film becomes strong, and as a result, the splitting properties in the cooling expansion step is improved, but the mechanism is not limited thereto.

The loss tangent at 0° C. may be 0.15 or less, 0.14 or less, 0.13 or less, 0.12 or less, 0.11 or less, 0.10 or less, 0.08 or less, 0.06 or less, or 0.04 or less because a dicing/die-bonding integrated film excellent in splitting properties by cooling expansion is further easily obtained. The loss tangent may be 0.01 or more, or 0.02 or more.

The loss tangent at 0° C. can be controlled to fall within the above-mentioned numerical range, for example, by adjusting the composition of the pressure-sensitive adhesive (For example, the pressure-sensitive adhesive composition, the amount of the crosslinking agent used, the kind and amount of the initiator used, and the like) constituting the pressure-sensitive adhesive layer.

The thickness of the dicing film 5 (the total of the thickness of the substrate film 3 and the thickness of the pressure-sensitive adhesive layer 2) may be 60 to 150 μm or 70 to 130 μm from the viewpoint of economic efficiency and film handleability.

### <Pressure-sensitive Adhesive Layer>

The pressure-sensitive adhesive layer 2 may be a layer formed of a pressure-sensitive adhesive usually used in dicing films. The pressure-sensitive adhesive constituting the pressure-sensitive adhesive layer 2 may be an ultraviolet curable pressure-sensitive adhesive or a non-ultraviolet curable pressure-sensitive adhesive. The ultraviolet curable pressure-sensitive adhesive is a pressure-sensitive adhesive having a property that the pressure-sensitive adhesive properties is lowered by ultraviolet irradiation. By using the ultraviolet curable pressure-sensitive adhesive, for example, the pressure-sensitive adhesive force of the pressure-sensitive adhesive layer 2 can be reduced by ultraviolet irradiation before picking up the semiconductor chip to which the die-bonding film piece is attached.

The ultraviolet curable pressure-sensitive adhesive may contain, for example, an acrylic resin having a (meth)acryloyl group. The acrylic resin may have, for example, a hydroxyl group. The acrylic resin is a polymer containing a (meth)acrylic acid ester as a monomer unit. The ultraviolet curable pressure-sensitive adhesive may further contain other components such as a photopolymerization initiator and a crosslinking agent (for example, polyisocyanate compounds) as necessary. The crosslinking agent is a compound having a reactive group that reacts with the acrylic resin. Examples of the crosslinking agent include a polyisocyanate compound.

The thickness of the pressure-sensitive adhesive layer 2 may be 20 μm or less, 18 μm or less, 16 μm or less, 14 μm or less, 12 μm or less, 10 μm or less, 8 μm or less, 6 μm or less, 4 μm or less, or 2 μm or less because a dicing/die-bonding integrated film excellent in splitting properties by cooling expansion is further easily obtained. The thickness of the pressure-sensitive adhesive layer 2 may be, for example, 1 μm or more, 3 μm or more, or 5 μm or more from the viewpoint of pressure-sensitive adhesive properties during cooling expansion and adhesive properties to a dicing ring. The thickness of the pressure-sensitive adhesive layer 2 may be, for example, 1 to 10 μm.

The ratio of the thickness (unit: μm) of the pressure-sensitive adhesive layer 2 to the thickness (unit: μm) of the substrate film 3 may be less than 1, ½ or less, ⅓ or less, ¼ or less, ⅙ or less, ⅛ or less, 1/10 or less, or 1/15 or less. The ratio of the thickness (unit: μm) of the pressure-sensitive adhesive layer 2 to the thickness (unit: μm) of the substrate film 3 may be 1/150 or more, 1/125 or more, 1/100 or more, 1/75 or more, or 1/50 or more.

The thickness (unit: μm) of the pressure-sensitive adhesive layer 2 with respect to the thickness (unit: μm) of the dicing film 5 may be less than 1, ½ or less, ¼ or less, ⅙ or less, ⅛ or less, 1/10 or less, or 1/15 or less, or may be 1/100 or more, 1/75 or more, or 1/50 or more.

### <Substrate Film>

The resin constituting substrate film 3 includes a homopolymer of an olefin such as ethylene, propylene, butene, hexene, methylpentene, 4-methyl-1-pentene, or vinyl acetate, or a copolymer thereof; polyesters such as polyethylene terephthalate and polyethylene naphthalate; ethylene copolymers such as an ethylene-vinyl acetate copolymer, an ethylene-(meth)acrylic acid copolymer, an ethylene-(meth)acrylic acid ester copolymer, and an ethylene-(meth)acrylic acid-(meth)acrylic acid ester copolymer; an ionomer resin having an ionically crosslinked structure by salt formation of an acid moiety and a metal ion (a sodium ion, a zinc ion, etc.) in a copolymer containing an olefin such as ethylene and (meth)acrylic acid; engineering plastics such as polycarbonate, polyamide, polyimide, polyether ether ketone, polyether imide, wholly aromatic polyamide, and polyphenyl sulfide; aramid (paper); glass; glass cloth; fluorine-based resin; chlorine-based resin such as polyvinyl chloride and polyvinylidene chloride; cellulose-based resin; silicone-based resin; or, a mixture obtained by mixing these with a plasticizer, a cured product crosslinked by electron beam irradiation, or the like. The substrate film may be composed of a single kind of resin, or may be composed of a mixed resin obtained by mixing two or more kinds of resins. The substrate film may be a film having a layered structure in which two or more kinds of films are layered. The substrate film may be subjected to a surface roughening treatment such as a mat treatment or a corona treatment from the viewpoint of controlling adhesive properties to the pressure-sensitive adhesive layer 2. The substrate film 3 may be a substrate film containing at least one resin selected from the group consisting of polyester, an ethylene copolymer, an ionomer resin, and an engineering plastic.

The substrate film 3 can be produced by forming a film by a conventionally known method. For example, the film can be produced by melt-kneading by melt-kneading a resin composition prepared by adding additives such as an antistatic agent to the resin raw material of the substrate as required, and processing the resulting composition into a film shape by various molding methods such as a T-die casting method, a T-die nip molding method, an inflation molding method, an extrusion lamination method, and a calendering method. When the substrate film has a layered structure, a layered structure can be produced by separately forming each layer by means such as a calendering method, an extrusion method, or an inflation molding method, and laminating the layers by means such as thermal lamination or bonding with an adhesive. As the adhesive, an adhesive usually used in producing a layered structure can be used. A layered structure can also be produced by simultaneously extruding the resin composition of each layer by a co-extrusion lamination method. In addition, the surface of the substrate film on the side opposite to the surface on the side in contact with the pressure-sensitive adhesive layer may be subjected to embossing treatment or the like with an embossing roll for the purpose of stabilizing winding at the time of producing the substrate film 3 and preventing blocking after film formation.

The thickness of the substrate film 3 may be 20 μm or more, 30 μm or more, 40 μm or more, 50 μm or more, 60 μm or more, 70 μm or more, or 80 μm or more because a dicing/die-bonding integrated film excellent in splitting properties by cooling expansion can be more easily obtained. The thickness of the substrate film 3 may be 200 μm or less, 150 μm or less, 130 μm or less, 110 μm or less, 100 μm or less, or 90 μm or less from the viewpoint of economic advantage. The thickness of the substrate film 3 may be, for example, 30 to 150 μm or 30 to 90 μm.

The shape of the substrate film 3 may have a rectangular principal surface, but is not limited thereto. The substrate film 3 may be a long film, and for example, a plurality of pressure-sensitive adhesive layers 2 may be disposed on one long substrate film 3.

### <Method for Manufacturing Dicing Film>

The dicing film 5 can be manufactured, for example, by a method including a step of selecting a dicing film having a loss tangent at 0° C. of 0.15 or less as described above (selection step).

[Dicing/die-bonding Integrated Film]

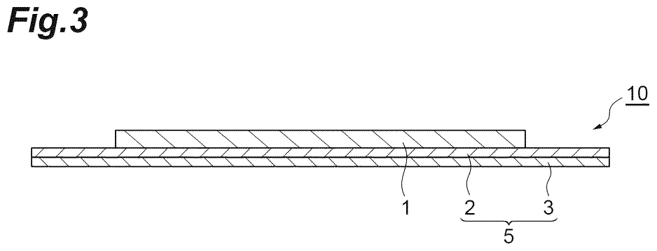

FIG. 3 is a schematic cross-sectional view showing an embodiment of a dicing/die-bonding integrated film including the above-described dicing film. The dicing/die-bonding integrated film 10 includes a die-bonding film 1 (Hereinafter, the die-bonding film may be referred to as an “bonding adhesive layer”.) and a dicing film 5 having a pressure-sensitive adhesive layer 2 bonded to the die-bonding film 1.

The die-bonding film 1 is an adhesive film for bonding a semiconductor chip to a substrate or another semiconductor chip, and is sometimes referred to as a die attach film (DAF). The die-bonding film 1 has, for example, a circular principal surface that covers the entire principal surface of the semiconductor wafer.

The thickness of the die-bonding film 1 (bonding adhesive layer) may be, for example, 150 μm or less, 120 μm or less, 100 μm or less, 70 μm or less, 60 μm or less, 50 μm or less, 40 μm or less, 30 μm or less, 25 μm or less, or 20 μm or less, or may be 3 μm or more, 5 μm or more, 7 μm or more, or 10 μm or more.

The die-bonding film 1 may be a film formed of an adhesive usually used for bonding semiconductor chips. The die-bonding film 1 may be a thermosetting adhesive. The thermosetting adhesive constituting the die-bonding film 1 contains, for example, a thermosetting component and a high molecular weight resin component (elastomer).

The thermosetting component is a compound (resin) having a reactive group that forms a crosslinked structure by self-polymerization and/or reaction with a curing agent. The thermosetting component may contain, for example, an epoxy resin, and may contain, in addition to the epoxy resin, a phenol resin that acts as a curing agent for the epoxy resin. The content of the thermosetting component may be 5 to 250 parts by mass with respect to 100 parts by mass of the total amount of the die-bonding film.

The high molecular weight resin component (elastomer) may contain, for example, at least one resin selected from the group consisting of an acrylic rubber, a polyimide, and a phenoxy resin, and may contain an acrylic rubber. The high molecular weight resin component may have a reactive group such as an epoxy group. The weight average molecular weight (value in terms of standard polystyrene by GPC method) of the high molecular weight resin component may be 100,000 to 3,000,000. The content of the high molecular weight resin component may be 30 to 80 parts by mass with respect to 100 parts by mass of the total amount of the die-bonding film.

The thermosetting adhesive may contain other components as necessary. Examples of other components include a curing accelerator that accelerates the reaction between the epoxy resin and the phenolic resin, a coupling agent (For example, a silane coupling agent), and an inorganic filler (For example, silica).

The dicing/die-bonding integrated film can be suitably used in a method for manufacturing a semiconductor device including a step of individuating a die-bonding film by expanding the dicing film under cooling conditions (For example, 0° C. or lower) to produce a semiconductor chip with the die-bonding film piece.

<Method for Manufacturing Dicing/die-bonding Integrated Film>

The dicing/die-bonding integrated film 10 can be manufactured, for example, by a method including a step of bonding a die-bonding film and the pressure-sensitive adhesive layer 2 of the dicing film 5 to each other.

### [Method for Manufacturing Semiconductor Device]

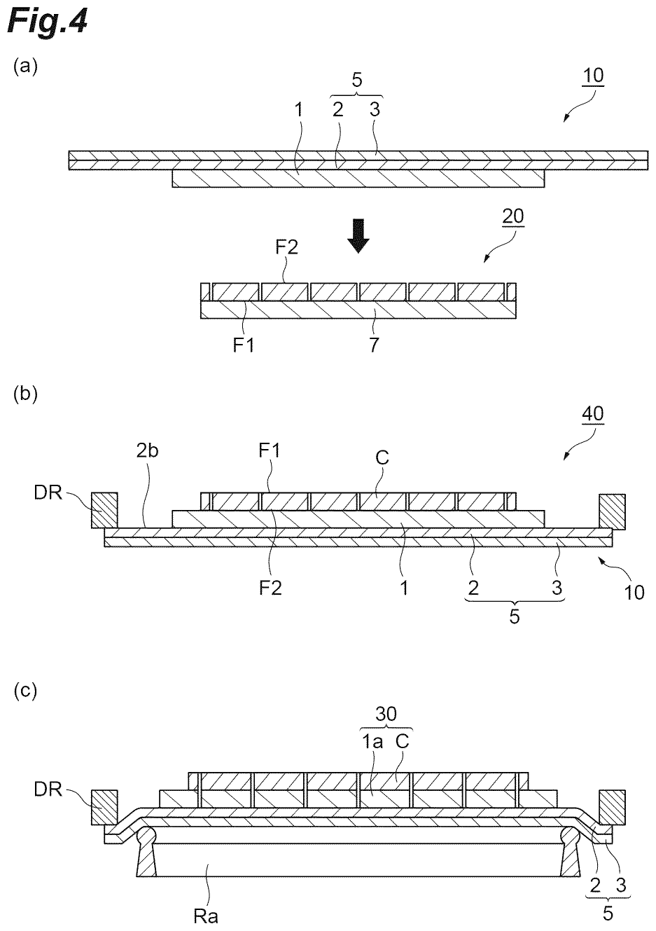

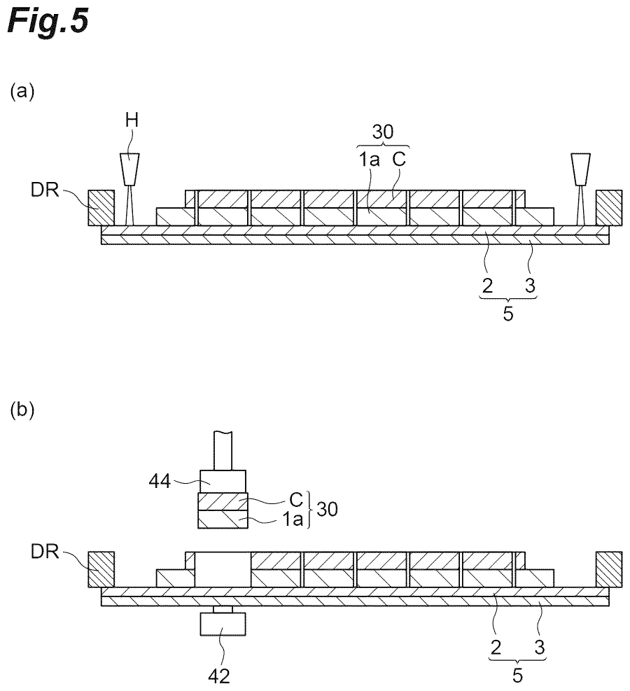

FIGS. 4 and 5 are cross-sectional views schematically illustrating a method for manufacturing a semiconductor device. A method for manufacturing a semiconductor device includes the steps of: (A) preparing a layered body 40 including a dicing/die-bonding integrated film 10 including a dicing film 5 having a substrate film 3 and a pressure-sensitive adhesive layer 2 provided on the substrate film 3, and a die-bonding film 1 provided on the pressure-sensitive adhesive layer 2, and a plurality of semiconductor chips C formed by individuating a semiconductor wafer, and provided on the die-bonding film 1 of the dicing/die-bonding integrated film 10; and (B) expanding the dicing film 5 of the layered body 40 under cooling conditions to individuate the die-bonding film 1, thereby producing a semiconductor chip 30 with a die-bonding film piece having a semiconductor chip C and a die-bonding film piece 1a obtained by individuating the die-bonding film 1. The method for manufacturing a semiconductor device may further include the steps of: (C) picking up the semiconductor chip 30 with the die-bonding film piece from the pressure-sensitive adhesive layer 2; and (D) mounting the picked-up semiconductor chip 30 with the die-bonding film piece on a substrate or another semiconductor chip.

The semiconductor chip C is formed by individuating a semiconductor wafer. The semiconductor wafer may be a silicon wafer, and the semiconductor chip C may be a silicon chip. The semiconductor chip C has a principal surface F1 and a principal surface F2. For example, the principal surface F1 may be a circuit surface (front surface), and the principal surface F2 may be a back surface opposite to the circuit surface.

As the thickness of the semiconductor wafer, for example, a wafer having a thickness of 8 inches or 12 inches can be used.

The method for individuating the semiconductor wafer may be a stealth dicing method such as a stealth dicing before grinding (SDBG) method or a half-cut dicing method such as a dicing before grinding (DBG) method.

The stealth dicing method can be a method including, for example, a step of attaching a protective tape (back grinding tape) to a circuit surface of a semiconductor wafer, a step of forming a reformation region inside the semiconductor wafer by irradiation with a laser beam, and a step of grinding the semiconductor wafer from a back surface side and cleaving the semiconductor wafer with the reformation region as a division starting point.

The half-cut dicing method can be a method including, for example, a step of forming a groove on a front surface of a semiconductor wafer with a dicing blade, a step of attaching a protective tape (back grinding tape) to a circuit surface of the semiconductor wafer, and a step of grinding the semiconductor wafer from a back surface side to the groove.

By such a method for individuating a semiconductor wafer, it is possible to obtain the layered body 20 including a protective tape 7 (back grinding tape) and the plurality of semiconductor chips C provided on the protective tape 7 (see FIG. 4(a)). In the layered body 20, the semiconductor chip C is provided on the protective tape 7.

The thickness of the semiconductor chip C is smaller than the thickness of the semiconductor wafer, and may be, for example, 10 to 200 μm. The thickness of the semiconductor chip C may be 15 μm or more or 20 μm or more, and may be 150 μm or less, 100 μm or less, or 50 μm or less.

Subsequently, the die-bonding film 1 is attached to the semiconductor chip C under a heating condition in a direction in which the die-bonding film 1 of the dicing/die-bonding integrated film 10 is in contact with the principal surface F2 of the semiconductor chip C (see FIG. 4(a)). The temperature of the heating condition may be, for example, 40 to 80° C. As a result, it is possible to obtain the layered body 40 including the dicing/die-bonding integrated film 10 and the plurality of semiconductor chips C provided on the die-bonding film 1 of the dicing/die-bonding integrated film 10 and formed by individuating the semiconductor wafer. At the same time as the die-bonding film 1 is attached to the semiconductor chip C, the dicing ring DR is attached to the principal surface 2b of the pressure-sensitive adhesive layer 2 on the die-bonding film 1 side so as to surround the plurality of semiconductor chips C (see FIG. 4(b)). At the timing of bonding to the semiconductor chip C, the layered body 40 may include a dicing ring DR on the principal surface 2b of the pressure-sensitive adhesive layer 2 on the die-bonding film 1 side. The protective tape 7 is peeled off from the semiconductor chip C at an appropriate timing.

Subsequently, the dicing film 5 is expanded (stretched) by pushing up the region inside the dicing ring DR of the dicing film 5 with the ring Ra under the cooling condition (see FIG. 4(c)). The temperature of the cooling condition may be, for example, −15 to 0° C. By expanding the dicing film 5, the die-bonding film 1 is split. By this split, the semiconductor chip 30 with the die-bonding film piece including the semiconductor chip C and the die-bonding film piece 1a obtained by individuating the die-bonding film 1 is formed on the pressure-sensitive adhesive layer 2.

After the ring Ra is lowered, in the dicing film 5, a region between the dicing ring DR and the semiconductor chip 30 with the die-bonding film piece is heated by the heater H (see FIG. 5(a)). Due to thermal shrinkage of the dicing film 5 in the heated part, the kerf width between the semiconductor chip 30 with the die-bonding film piece tends to further increase.

When the pressure-sensitive adhesive layer 2 is a layer formed of an ultraviolet curable pressure-sensitive adhesive, the pressure-sensitive adhesive force of the pressure-sensitive adhesive layer 2 can be reduced by ultraviolet irradiation. After reducing the pressure-sensitive adhesive force of the pressure-sensitive adhesive layer 2, the individual semiconductor chip 30 with the die-bonding film piece pushed up by the push-up jig 42 is picked up by a protrusion jig 44 (see FIG. 5(b)).

The picked-up semiconductor chip 30 with the die-bonding film piece is mounted on a substrate or another semiconductor chip. By layering a plurality of semiconductor chips, for example, a 3D NAND flash memory can be manufactured.

### EXAMPLES

Hereinafter, the present disclosure will be specifically described based on examples, but the present disclosure is not limited thereto.

### Example 1

### 1-1. Production of Pressure-sensitive Adhesive Layer (Manufacture Example A-1)

An acrylic polymer 1 which is a copolymer of the following monomers was prepared. The acrylic polymer 1 has a weight average molecular weight (Mw) of 910,000, a number average molecular weight (Mn) of 140,000, and Mw/Mn of 6.5. The hydroxyl value of the acrylic polymer 1 is 2.5 mgKOH/g.
Butyl acrylate: 88.1 parts by mass
2-Hydroxyethyl methacrylate: 0.6 parts by mass
Acrylic acid nitrile: 11.2 parts by mass

A pressure-sensitive adhesive solution A-1 was prepared by blending Coronate L38ET (TMP adduct of tolylene diisocyanate, manufactured by Tosoh Corporation, Nv 37.5%, TDI adduct trifunctional NCO % 6.6%) as a crosslinking agent was blended at a ratio of 2.2 parts by mass in terms of solid content with respect to 100 parts by mass in terms of solid content of the acrylic polymer 1, and the blend was diluted with methyl ethyl ketone (MEK) and stirring the blend.

The pressure-sensitive adhesive solution A-1 was applied onto a polyethylene terephthalate film (thickness: 38 μm) having one surface subjected to release treatment so that the thickness after drying was 10 μm, and dried at 80° C. for 3 minutes to form a pressure-sensitive adhesive layer of Manufacture Example A-1 on the polyethylene terephthalate film.

### 1-2. Production of Substrate Film (Manufacture Example B-1)

A resin which was a terpolymer having a mass ratio of ethylene/methacrylic acid/2-methyl-propyl acrylate=80/10/10, and had a neutralization degree by Zn²⁺ ion: 60 mol %, a melting point: 86° C., an MFR: 1 g/10 min (190° C./2.16 kg load), and a density: 0.96 g/cm³ was formed into a 90 μm film, and the film used as a substrate film of Manufacture Example B-1.

### 1-3. Production of Dicing Film

A substrate film (Manufacture Example B-1) subjected to corona discharge treatment at one surface was bonded to the pressure-sensitive adhesive layer of Manufacture Example A-1. The bonded sample was aged in a thermostatic chamber at 23° C. for 96 hours to produce a dicing film.

### 1-4. Production of Bonding Adhesive Layer (Manufacture Example C-1)

100 parts by weight of HTR-860P-3(trade name, glycidyl group-containing acrylic rubber, manufactured by Nagase ChemteX Corporation, molecular weight: 1 million, Tg: −7° C.), 20 parts by weight of YDCN-700-10 (trade name, o-cresol novolac epoxy resin, epoxy equivalent: 210, manufactured by Nippon Steel & Sumikin Chemical Co., Ltd.), 17 parts by weight of MILEX XLC-LL (trade name, phenol aralkyl resin, manufactured by Mitsui Chemicals, Inc.), 0.04 parts by weight of 1-(2-cyanoethyl)-2-phenylimidazole (2PZ-CN), 12 parts by weight of AEROSIL R972 (trade name, silica, manufactured by Nippon Aerosil Co., Ltd., average particle diameter 0.016 μm), 0.6 parts by weight of A-189 (trade name, γ-mercaptopropyltrimethoxysilane, manufactured by Nippon Unicar Company Limited) and 1.7 parts by weight of A-1170 (trade name, γ-ureidopropyltriethoxysilane, manufactured by Nippon Unicar Company Limited) were added thereto, and the mixture was vacuum-degassed. This adhesive varnish was applied onto a surface release-treated polyethylene terephthalate (Teijin Tetoron film A-31 manufactured by Teijin DuPont Films) having a thickness of 75 μm to obtain a bonding adhesive layer (die-bonding film) having a thickness of 20 μm.

1-5. Production of Dicing/die-bonding Integrated Film (Example 1)

A bonding adhesive layer (die-bonding film) and a dicing film were bonded to each other such that the bonding adhesive layer of the die-bonding film and the pressure-sensitive adhesive layer of the dicing film were in contact with each other to obtain a dicing/die-bonding integrated film of Example 1.

### Example 2

### 2-1. Production of Pressure-sensitive Adhesive Layer (Manufacture Example A-2)

An acrylic polymer 2 which is a copolymer of the following monomers was prepared. The acrylic polymer 2 has a weight average molecular weight (Mw) of 610,000, a number average molecular weight (Mn) of 140,000, and Mw/Mn of 4.4. The hydroxyl value of the acrylic polymer 2 is 19.5 mgKOH/g.
Butyl acrylate: 71.2 parts by mass
2-Hydroxyethyl methacrylate: 4.8 parts by mass
Acrylic acid nitrile: 24.0 parts by mass

A pressure-sensitive adhesive solution A-2 was prepared by blending 70 parts by mass of the acrylic polymer 1 in terms of solid content, 30 parts by mass of the acrylic polymer 2 in terms of solid content, and 2.2 parts by mass of Coronate L38ET (TMP adduct of tolylene diisocyanate, manufactured by Tosoh Corporation, Nv 37.5%, TDI adduct trifunctional NCO % 6.6%) as a crosslinking agent in terms of solid content, diluting the blend with methyl ethyl ketone (MEK), and stirring the blend. A pressure-sensitive adhesive layer of Manufacture Example A-2 was produced in the same manner as in Manufacture Example A-1 except that the pressure-sensitive adhesive solution A-2 was used in place of the pressure-sensitive adhesive solution A-1.

2-2. Production of Dicing/die-bonding Integrated Film (Example 2)

A dicing/die-bonding integrated film of Example 2 was produced in the same manner as Example 1 except that the pressure-sensitive adhesive layer of Manufacture Example A-2 was used as the pressure-sensitive adhesive layer.

### Comparative Example 1

### 3-1. Production of Pressure-sensitive Adhesive Layer (Manufacture Example A-3)

As copolymerizable monomer components, 2-ethylhexyl acrylate (EHA), 2-hydroxyethyl acrylate (HEA), and methyl methacrylate (MMA) were prepared. These copolymerizable monomer components were mixed so as to have a copolymerization ratio of EHA/HEA/MMA=78 parts by mass/21 parts by mass/1 part by mass, ethyl acetate was used as a solvent, and 0.08 parts by mass of azobisisobutyronitrile (AIBN) was used as an initiator, and an acrylic copolymer was obtained by solution radical polymerization. The acrylic copolymer was reacted with 0.05 parts by mass of hydroquinone monomethyl ether as a polymerization inhibitor and 16 parts by mass of 2-methacryloyloxyethyl isocyanate (trade name: Karenz MOI, molecular weight: 155.15) to synthesize an ultraviolet curable pressure-sensitive adhesive having a carbon-carbon double bond. The weight average molecular weight of the obtained ultraviolet curable pressure-sensitive adhesive was 350,000. The hydroxyl value and the acid value of the ultraviolet curable pressure-sensitive adhesive were 37.6 mgKOH/g and 6.5 mgKOH/g, respectively. A pressure-sensitive adhesive solution A-3 was prepared by blending 100 parts by mass of the obtained ultraviolet curable pressure-sensitive adhesive in terms of solid content, 1.0 parts by mass of an a-hydroxyalkylphenone-based photopolymerization initiator (trade name: Omnirad 184) manufactured by IGM Resins B.V., 0.2 parts by mass of an acylphosphine oxide-based photopolymerization initiator (trade name: Omnirad 819) manufactured by IGM Resins B.V., and 2.07 parts by mass of a TDI-based polyisocyanate-based crosslinking agent (trade name: Coronate L-45E) manufactured by Tosoh Corporation as a crosslinking agent in terms of solid content were blended, diluting the blend with ethyl acetate and stirring the blend. A pressure-sensitive adhesive layer of Manufacture Example A-3 was produced in the same manner as in Manufacture Example A-1 except that the pressure-sensitive adhesive solution A-3 was used in place of the pressure-sensitive adhesive solution A-1.

3-2. Production of Dicing/die-bonding Integrated Film Comparative Example 1

A dicing/die-bonding integrated film of Comparative Example 1 was produced in the same manner as in Example 1 except that the pressure-sensitive adhesive layer of Manufacture Example A-3 was used as the pressure-sensitive adhesive layer.

### Comparative Example 2

### 4-1. Production of Pressure-sensitive Adhesive Layer (Manufacture Example A-4)

A pressure-sensitive adhesive solution A-4 was produced by blending 100 parts by mass of the ultraviolet curable pressure-sensitive adhesive prepared in Manufacture Example A-3 in terms of solid content, 1.0 parts by mass of an α-hydroxyalkylphenone-based photopolymerization initiator (trade name: Omnirad184) manufactured by IGM Resins B.V., 0.2 parts by mass of an acylphosphine oxide-based photopolymerization initiator (trade name: Omnirad819) manufactured by IGM Resins B.V., and 4.14 parts by mass in terms of solid content of a TDI-based polyisocyanate-based crosslinking agent (trade name: Coronate L-45E) manufactured by Tosoh Corporation as a crosslinking agent, diluting the blend with ethyl acetate and stirring the blend. A pressure-sensitive adhesive layer of Manufacture Example A-4 was produced in the same manner as in Manufacture Example A-1 except that the pressure-sensitive adhesive solution A-4 was used in place of the pressure-sensitive adhesive solution A-1.

4-2. Production of Dicing/die-bonding Integrated Film Comparative Example 2

A dicing/die-bonding integrated film of Comparative Example 1 was produced in the same manner as in Example 1 except that the pressure-sensitive adhesive layer of Manufacture Example A-4 was used as the pressure-sensitive adhesive layer.

### Examples 3 to 5

### 5-1. Production of Pressure-sensitive Adhesive Layer (Manufacture Example A-5)

An ultraviolet curable pressure-sensitive adhesive was synthesized by the same method as that for producing the ultraviolet curable pressure-sensitive adhesive in Comparative Example 1 except that 19 parts by mass of 2-methacryloyloxyethyl isocyanate (trade name: Karenz MOI, molecular weight: 155.15) was reacted at a copolymerization ratio of EHA/HEA/MMA=78 parts by mass/21 parts by mass/1 part by mass as copolymerizable monomer components. The weight average molecular weight of the obtained ultraviolet curable pressure-sensitive adhesive was 350,000. The obtained ultraviolet curable pressure-sensitive adhesive had a hydroxyl value and an acid value of27.5 mgKOH/g and 6.5 mgKOH/g, respectively. A pressure-sensitive adhesive layer of Manufacture Example A-5 was produced in the same manner as in Manufacture Example A-1 except that the obtained ultraviolet curable pressure-sensitive adhesive was used and the thickness of the pressure-sensitive adhesive layer was changed to be the thickness shown in Table 2.

5-2. Production of Dicing/die-bonding Integrated Film (Example 3 to 5)

A dicing/die-bonding integrated film of Example 3 to 5 was produced in the same manner as in Example 1 except that the pressure-sensitive adhesive layer of Manufacture Example A-5 was used as the pressure-sensitive adhesive layer and the thickness of the adhesive layer of Manufacture Example C-1 was changed to 7 μm.

### 6. Evaluation

### <Measurement of Hydroxyl Value and Acid Value>

The hydroxyl value was measured in accordance with the method described in JIS K0070:1992. The acid value was measured in accordance with the method described in JIS K2501:2003.

### <Measurement of Weight Average Molecular Weight and Number Average Molecular Weight>

The weight average molecular weight and the number average molecular weight are values in terms of standard polystyrene by a GPC method. The details of the measurement conditions are as follows.

GPC measurement was performed using SD-8022/DP-8020/RI-8020 manufactured by Tosoh Corporation, using Gelpack GL-A150-S/GL-A160-S manufactured by Hitachi Chemical Co., Ltd. as a column, and using tetrahydrofuran as an eluent.

### <Measurement of Loss Tangent>

A dicing film having a rectangular principal surface with a short side of 5 mm and a long side of 8 mm was prepared as a measurement sample. The measurement sample was disposed on a solid shearing jig as shown in FIG. 2, and the MD direction (Machine Direction: a direction parallel to the longitudinal direction (flow direction) in the original fabric that provides the substrate film) of the substrate film was fixed as a short side. Viscoelasticity was measured under the following device and measurement conditions, and the loss tangent (0° C. tan δ) at 0° C. was determined.

### [Device Information]

“Dynamic viscoelasticity measuring device (DMA)” Rheogel-E4000 manufactured by UBM Co., Ltd.

### [Measurement Conditions]

Measurement jig: solid shearing jig M039
Frequency: 10 Hz
Sine wave
Strain (strain amount): total thickness ratio 1%
Sample size: 5×8 mm
Heating rate: 2° C./min
Clamping pressure: Torque wrench 9 cN·m

### <Evaluation of Splitting Properties>

### [Production of Sample for Evaluation]

An evaluation sample was produced according to the following procedure. A protective tape was attached to the surface of a silicon wafer (diameter: 12 inch, thickness: 775 μm). Thereafter, the silicon wafer was individualized by stealth dicing. That is, the reformation region was formed inside the silicon wafer by irradiating the surface (back surface) of the silicon wafer opposite to the side to which the protective tape was attached with the laser beam under the following conditions.

### (Stealth Dicing Conditions)

Stealth dicing device: DFL7361 (manufactured by DISCO Corporation)
Laser oscillator type: Semiconductor laser excitation q switch solid laser
Wavelength: 1342 nm
Frequency: 60 kHz
Output: 0.8 W
Number of passes: 2
Chip size: 3 mm×12 mm
Dicing speed: 800 mm/sec

Subsequently, the surface of the silicon wafer opposite to the protective tape was ground (polished) using a grinder polisher device (DGP8761, manufactured by DISCO Corporation) until the thickness of the silicon wafer reached 30 μm, and the silicon wafer was individualized to obtain silicon chips. A die-bonding film of a dicing/die-bonding integrated film was attached to a surface of a silicon chip opposite to the protective tape under the following attachment conditions. At this time, the direction of attaching was adjusted so that the direction of the division line of the silicon chip was along the MD direction and the TD direction (Transverse Direction, direction orthogonal to MD direction (vertical direction)) of the substrate film of the dicing/die-bonding integrated film. The silicon wafer was attached such that the long side of the chip was perpendicular to the MD direction. Further, the pressure-sensitive adhesive layer in a part protruding from the die-bonding film was attached to the dicing ring, and then the protective tape was peeled off from the silicon wafer.

### (Attachment Condition)

Attachment device: DFM2800 (manufactured by DISCO Corporation)
Attachment temperature: 65° C.
Attachment speed: 10 mm/s
Attachment tension level: Level 5

Then, using a die separator (DDS2300, manufactured by DISCO Corporation), the dicing film of the dicing/die-bonding integrated film was stretched by cooling expansion under the following cooling expansion conditions, thereby dividing the die-bonding film.

### (Cooling Expansion Conditions)

Cooling temperature: 0° C.
Cooling time: 120 seconds
Protrusion amount: 8 mm
Protrusion speed: 120 mm/see
Retention time after protrusion: 10 seconds

### [Evaluation of Splitting Properties]

For the sample after dividing the die-bonding film by cooling expansion, the splitting properties was evaluated by the following procedure. The results are shown in Tables 1 to 2.

Using a measuring microscope (MF-U) manufactured by Mitutoyo Corporation, the split state of the die-bonding film was confirmed by enlarging and observing between the chips in a direction along the long side (12 mm) of the chip from above the chip and in a direction along the short side (3 mm) of the chip. The observation subjects were each of the 216 locations in A and B the long side of the chip and the short side of the chip (total number of observations: 432). The long side of the chip and the short side of the chip which were observation subjects were selected from one side (216 long sides, 216 short sides, 432 points in total) of the chip formed by being divided by any one of the division lines of the third column, the eighth column, the 13 column, the 18 column, and the 23 column among the 26 columns of division lines in the direction along the short side of the chip. When the entire side of the die-bonding film was cut, it was determined as OK, and when the entire side or part of the film remained uncut, it was determined as NG. The splitting properties was evaluated by the splitting properties NG rate obtained by the formula: (number of NGs/total number of observations)×100. The case where the splitting properties NG rate was 1% or less was evaluated as “A”, the case where the splitting properties NG rate was more than 1% and 3% or less was evaluated as “B”, and the case where the splitting properties NG rate was more than 3% was evaluated as “C”.

TABLE 1

| | | | | | Comparative | Comparative |
|---|---|---|---|---|---|---|
| | | | Example 1 | Example 2 | Example 1 | Example 2 |
| Dicing | Pressure- | Kind | Manufacture | Manufacture | Manufacture | Manufacture |
| film | sensitive | | Example A-1 | Example A-2 | Example A-3 | Example A-4 |
| | adhesive | Thickness | 10 | 10 | 10 | 10 |
| | layer | (μm) | | | | |
| | Substrate | Kind | Manufacture Example B-1 | | | |
| | film | Thickness | 90 | 90 | 90 | 90 |
| | | (μm) | | | | |
| | 0° C. tan δ | | 0.09 | 0.06 | 0.22 | 0.17 |
| Die- | Bonding | Kind | Manufacture Example C-1 | | | |
| bonding | Adhesive | Thickness | 20 | 20 | 20 | 20 |
| film | layer | (μm) | | | | |

| | | | | | |
|---|---|---|---|---|---|
| Evaluation | Splitting properties | B (3%) | A1 (1%) | C (44%) | C (27%) |

TABLE 2

| | | | Example 3 | Example 4 | Example 5 |
|---|---|---|---|---|---|
| Dicing film | Pressure- | Kind | Manufacture Example A-5 | | |
| | sensitive | Thickness | 10 | 2 | 5 |
| | adhesive | (μm) | | | |
| | layer | | | | |
| | Substrate | Kind | Manufacture Example B-1 | | |
| | film | Thickness | 90 | 90 | 90 |
| | | (μm) | | | |
| | 0° C. tan δ | | 0.13 | 0.03 | 0.05 |
| Die- | Bonding | Kind | Manufacture Example C-1 | | |
| bonding | Adhesive | Thickness | 7 | 7 | 7 |
| film | layer | (μm) | | | |

| | | | | |
|---|---|---|---|---|
| Evaluation | Splitting properties | B (3%) | A (0%) | A (0%) |

As shown in Table 1 to 2, the dicing/die-bonding integrated films of Examples 1 to 5 in which the tan δ of the dicing film at 0° C. were 0.15 or less were superior in terms of splitting properties to the dicing/die-bonding integrated film of Comparative Example 1 to 2 in which the tan δ of the dicing film at 0° C. was more than 0.15.

From the above, according to the present disclosure, it has been confirmed that cooling splitting properties of a die-bonding film can be improved in a method for manufacturing a predetermined semiconductor device.

### REFERENCE SIGNS LIST

1 Die-bonding film
1a Die-bonding film piece
2 Pressure-sensitive adhesive layer
3 Substrate film
5 Dicing film
5A, 5B Measurement sample
7 Protective tape
10 Dicing/die-bonding integrated film
30 Semiconductor chip with die-bonding film piece
50 Solid shearing jig
51 First plate-shaped member
52a, 52b Second plate-shaped member
C Semiconductor chip

1. A dicing/die-bonding integrated film comprising:
a dicing film including a substrate film and a pressure-sensitive adhesive layer provided on the substrate film; and
a bonding adhesive layer composed of a die-bonding film and disposed on the pressure-sensitive adhesive layer of the dicing film,
wherein a loss tangent at 0° C. of the dicing film is 0.15 or less, and
wherein the loss tangent is a value determined by a method including:
preparing a measurement sample of the dicing film having a rectangular principal surface with a short side of 5 mm and a long side of 8 mm;
fixing, in a viscoelasticity measuring device (Rheogel-E4000, manufactured by UBM Co., Ltd.) including a solid shearing jig having a first plate-shaped member and a pair of second plate-shaped members, the measurement sample to the solid shearing jig by disposing two of the measurement samples in a direction in which the principal surface of the pressure-sensitive adhesive layer is in contact with the first plate-shaped member and the first plate-shaped member is sandwiched between the two measurement samples to clamp the measurement sample in a thickness direction under a condition that the clamping pressure applied by each of the pair of second plate-shaped members is a torque wrench 9 cN·m; and
determining the loss tangent by dynamic viscoelasticity measurement in a shear mode using the solid shearing jig to which the measurement sample is fixed under the conditions that a measurement frequency is 10 Hz, a strain amount is 1% in terms of the total thickness ratio of the dicing film, and a temperature raising rate is 2° C./min.

2. The dicing/die-bonding integrated film according to claim 1, wherein the loss tangent at 0° C. is 0.07 or less.

3. The dicing/die-bonding integrated film according to claim 1, wherein the pressure-sensitive adhesive layer has a thickness of 10 μm or less.

4. A method for manufacturing a dicing/die-bonding integrated film, the method comprising:
selecting a dicing film including a substrate film and a pressure-sensitive adhesive layer provided on the substrate film, the dicing film having a loss tangent at 0° C. of 0.15 or less; and
bonding a die-bonding film and the pressure-sensitive adhesive layer of the dicing film,
wherein the loss tangent is a value determined by:
preparing a measurement sample of the dicing film having a rectangular principal surface with a short side of 5 mm and a long side of 8 mm;
fixing, in a viscoelasticity measuring device (Rheogel-E4000, manufactured by UBM Co., Ltd.) including a solid shearing jig having a first plate-shaped member and a pair of second plate-shaped members, the measurement sample to the solid shearing jig by disposing two of the measurement samples in a direction in which the principal surface of the pressure-sensitive adhesive layer is in contact with the first plate-shaped member and the first plate-shaped member is sandwiched between the two measurement samples to clamp the measurement sample in a thickness direction under a condition that the clamping pressure applied by each of the pair of second plate-shaped members is a torque wrench 9 cN·m, and
determining the loss tangent by dynamic viscoelasticity measurement in a shear mode using the solid shearing jig to which the measurement sample is fixed under the conditions that a measurement frequency is 10 Hz, a strain amount is 1% in terms of a total thickness ratio of the dicing film, and a temperature raising rate is 2° C./min.

5. The dicing/die-bonding integrated film according to claim 1, wherein the loss tangent at 0° C. is 0.07 or less, and the pressure-sensitive adhesive layer has a thickness of 10 μm or less.

6. The dicing/die-bonding integrated film according to claim 1, wherein the loss tangent at 0° C. is 0.10 or less.

7. The dicing/die-bonding integrated film according to claim 1, wherein the pressure-sensitive adhesive layer has a thickness of 1 μm or more.

8. The dicing/die-bonding integrated film according to claim 1, wherein the pressure-sensitive adhesive layer has a thickness of 1 to 10 μm.

9. The dicing/die-bonding integrated film according to claim 1, wherein the substrate film has a thickness of 20 μm or more.

10. The dicing/die-bonding integrated film according to claim 1, wherein the substrate film has a thickness of 200 μm or less.

11. The method according to claim 4, wherein the loss tangent at 0° C. is 0.10 or less.

12. The method according to claim 4, wherein the loss tangent at 0° C. is 0.07 or less.

13. The method according to claim 4, wherein the pressure-sensitive adhesive layer has a thickness of 10 μm or less.

14. The method according to claim 4, wherein the pressure-sensitive adhesive layer has a thickness of 1 μm or more.

15. The method according to claim 4, wherein the pressure-sensitive adhesive layer has a thickness of 1 to 10 μm.

16. The method according to claim 4, wherein the substrate film has a thickness of 20 μm or more.

17. The method according to claim 4, wherein the substrate film has a thickness of 200 μm or less.

18. A method for manufacturing a semiconductor device, the method comprising:
preparing a layered body including:
the dicing/die-bonding integrated film according to claim 1; and
a plurality of semiconductor chips formed by individuating a semiconductor wafer, and provided on the die-bonding film of the dicing/die-bonding integrated film; and
expanding the dicing film of the layered body under cooling conditions to individuate the die-bonding film, thereby producing a semiconductor chip with a die-bonding film piece including a semiconductor chip and a die-bonding film piece.
